(19) United States
(12) Patent Application Publication
(10) Pub. No.: US 2008/0246503 A1
(43) Pub. Date: Oct. 9, 2008

(54) Method of testing a semiconductor integrated circuit

(75) Inventors: Sakurako Sumida, Chiba (JP); Akio Shirokane, Chiba (JP)

Correspondence Address: OLIFF & BERRIDGE, PLC, P.O. BOX 320850, ALEXANDRIA, VA, 22320-4850, US

(73) Assignee: KAWASAKI MICROELECTRONICS, INC., CHIBA (JP)

(21) Appl. No.: 12/078,699

(22) Filed: Apr. 3, 2008

(30) Foreign Application Priority Data
Apr. 9, 2007 (JP) 2007-101230

(51) Int. Cl. G01R 31/302

(52) U.S. Cl. 324/763

(57) ABSTRACT

A method of testing a semiconductor integrated circuit is disclosed. Specifically, a method of testing a semiconductor integrated circuit comprising a plurality of flip-flops is provided. The disclosed method includes connecting the plurality of flip-flops in series so that the plurality of flip-flops forms a scan-chain; inputting data to the scan-chain while supplying a clock signal to the plurality of flip-flops so that the data is set in the plurality of flip-flops; retaining the data in the plurality of flip-flops while inhibiting the clock signal for a predetermined period; restarting the clock signal to the plurality of flip-flops so that the data retained in the plurality of flip-flops is output from the scan-chain; and comparing the data output from the scan-chain and the data input to the scan-chain to test data retention of the plurality of flip-flops.

This application claims priority from Japanese Application No. 2007-A-101230, the disclosure of which is incorporated herein by reference in its entirety.

### BACKGROUND OF THE INVENTION

The trend in reduction in feature size and power-supply voltage continues in semiconductor integrated circuits. Logic circuits in semiconductor integrated circuits that operate at reduced power-supply voltages are composed of transistors with low threshold voltage, which operate at a high speed even at a low power supply voltage. However, the logic circuits with low threshold voltage transistors consume large current during periods that the logic circuits are not active. Accordingly, it has been proposed to stop supplying power to the logic circuits, and/or to suppress power consumption of the semiconductor integrated circuit, during a sleep mode or a stand-by mode. An example of such a proposal is presented in Japanese Patent Laid-Open No. H11-112297, which is incorporated by reference herein in its entirety. During the sleep mode, it is possible to stop supplying both the high supply voltage and the low supply voltages. It is also possible to stop supplying individually either one of the high supply voltage or the low supply voltages. During the sleep mode, data retention flip-flops are utilized for retaining the data.

It is possible to use a type of data retention flip-flop, to which the power supply voltage is always supplied, and only the supply of clock signal is stopped during the sleep mode. It is also possible to use another type of data retention flip-flop, in which the supply of power supply voltage is continued only to a selected portion necessary to retain the data, but the supply of power supply voltage to remaining portions is stopped during the sleep mode, thereby to further reduce the power consumption during the sleep mode.

FIG. 3 shows an exemplary data retention flip-flop 100A of the latter type. This type of data retention flip-flop is described, for example, in U.S. Patent Application Publication No. 2005/0184758, which is incorporated herein by reference in its entirety. In FIG. 3, INV1-INV8 are inverters, and G1 and G2 are transmission gates.

Inverters INV1, INV2, INV6, INV7 and INV8 are supplied with GND supply voltage through a NMOS transistor M17, which turns off when a sleep signal SLP is turned to “L”. NMOS transistor M17 is connected between the source (OFF) of each NMOS transistor and GND. NMOS transistor M11 and PMOS transistor M16 are connected in parallel between the source (SB) of NMOS transistor (not shown in FIG. 3) that constructs the INV4 and GND. NMOS transistor M15 turns off when the sleep signal SLP is turned to “L”. The gate of the PMOS transistor M16 is connected to GND. Accordingly, PMOS transistor M16, having a relatively large resistance, is always on.

Inverter INV3 is a clocked type inverter. Inverter INV3 is constructed with a CMOS inverter, which is composed of PMOS transistor M3 and NMOS transistor M4, and PMOS transistor M5 and NMOS transistor M6 connected in series with the CMOS inverter. The gate of PMOS transistor M5 is supplied with a reversed clock signal CLKB, and the gate of NMOS transistor M6 is supplied with a clock signal CLK. NMOS transistor M17 is connected between the source (OFF) of NMOS transistor M6 and GND.

Inverter INV5 is a clocked type inverter. Inverter INV5 is constructed with a CMOS inverter, which is composed of PMOS transistor M10 and NMOS transistor M11, and PMOS transistor M12 and NMOS transistor M13 connected in series with the CMOS inverter. The gate of PMOS transistor M12 is supplied with a clock signal CLK, and the gate of NMOS transistor M13 is supplied with a reversed clock signal CLKB. PMOS transistor M14, the gate of which is supplied with a data retention signal DR, is connected in parallel with NMOS transistor M12. The parallel connection of PMOS transistor M15 and NMOS transistor M116, which has been described above, is also connected between the source (SB) of transistor M13 and GND.

Inverter INV8 is constructed with a CMOS inverter, which is composed of PMOS transistor M19 and NMOS transistor M20, NMOS transistor M21, PMOS transistor M18, PMOS transistor M22, and NMOS transistor M17. NMOS transistor M21, the gate of which is supplied with the data retention signal DR, is connected in series with the CMOS inverter. PMOS transistor M18, the gate of which is supplied with the data retention signal DR, is connected to the gates of PMOS transistor M19 and NMOS transistor M20. PMOS transistor M22, the gate of which is supplied with the data retention signal DR, is connected to the drains of PMOS transistor M19 and NMOS transistor M20. NMOS transistor M17 is connected between the source (OFF) of transistor M21 and GND. The clock signal CK is converted into the clock signal CLK and the reversed clock signal CLKB by inverters INV7 and INV8.

Transmission gate G1 is composed of PMOS transistor M1 and NMOS transistor M2, which are connected in parallel. Transmission gate G2 is composed of PMOS transistor M7 and a serial connection of NMOS transistors M8 and M9, which are connected in parallel. The clock signal CLK is input to the gates of transistor M1 and M8. The reversed clock signal CLKB is input to the gates of transistor M2 and M7. The data retention signal DR is input to the gate of transistor M9.

In the data retention flip-flop 100A, the inverters INV2 and INV3, whose input and output terminals are reversely connected in parallel, operate as a master latch, and the inverters INV4 and INV5, whose input and output terminals are reversely connected in parallel, operate as a slave latch.

Assume that the sleep signal SLP is set to “H” and the data retention signal DR is set to “H”. Then, when the clock signal CK is turned to “L”, the clock signal CLK is turned to “L”, the reversed clock signal CLKB is turned to “H”. Accordingly, the transmission gate G1 turns on, the transmission gate G2 turns off, the inverter INV3 turns off and the inverter INV5 turns on. As a result, input data at the terminal D is input to inverter INV2 through the inverter INV1 and the transmission gate G1.

Next, when the clock signal CK is turned to “H”, the transmission gate G1 turns off, the transmission gate G2 turns on, the inverter INV3 turns on and the inverter INV5 turns off. Accordingly, the output data of the inverter INV2 is reversed in the inverter INV3 and input to the inverter INV2. The data is retained in the master latch. The retained data is input to the inverter INV4 through the transmission gate G2.

Next, when the clock signal CK is turned to “L”, the output data of the inverter INV4 is reversed by the inverter INV5, and is input to the inverter INV4. Therefore, the data is retained in the slave latch. This retained data is output to the terminal Q through the inverter INV6.

Thus, in the data retention flip-flop 100A, the master latch retains input data when the clock signal CK is turned to “H”. Then slave latch retains and outputs the data when the clock signal CK is turned to “L”.

Note that, when the clock signal CK is “L”, the clock signal CLK is “L” and the reversed clock signal CLKB is “H”. Therefore, the slave latch is separated from the master latch, because the transmission gate G2 turns off.

Then, assume that the data retention signal DR is turned to “L”. The transistor M18 and M22 turn on in inverter INV8, and both the clock signal CLK and the reversed clock signal CLKB are fixed to “H”. As a result, the transmission gate G2 remains off because the transistor M9 turns off, though the transistor M8 turns on. Therefore, the slave latch is kept separated. In the inverter INV5 of the slave latch, the transistor M14 turns on, though the transistor M12 turns off. Therefore, the slave latch keeps retaining the data.

Further, assume that the sleep signal SLP is turned to “L”. The transistor M17 turns off, and the power supply routes of the GND side of the inverters INV1, INV2, INV3, INV6, INV7 and INV8 are shut off, and they are in a power saving mode. At this time, a minimum power supply to the inverters INV4 and INV5 through the route formed by transistor M16 is maintained. Thus, the slave latch composed of inverters INV4 and INV5 retains the data.

### SUMMARY

As above mentioned, the data retention flip-flop 100A retains data, when the clock signal CK is fixed to “L”. The data retention flip-flop 100A also retains the data in the power saving mode, i.e., when the data retention signal DR is turned to “L” and the sleep signal SLP is turned to “L” in addition to the clock signal CK is fixed to “L”. Needless to say, however, the data retention flip-flop 100A needs to have sufficient data retention ability so that it properly performs a required data retention function in a semiconductor integrated circuit. That is, the data retention flip-flop 100A needs to retain the data for a period determined by the specification of a semiconductor integrated circuit. Thus, it is required to test the data retention ability of the flip-flop 100A before shipping the semiconductor integrated circuit that incorporates the data retention flip-flop 100A.

Exemplary embodiments according to this disclosure provide a method of testing a retention ability of the above mentioned flip-flops. Specifically, disclosed exemplary embodiments offer a method of simultaneously testing data retention abilities of a plurality of flip-flops.

In order to enable the above, this disclosure describes an exemplary method of testing a semiconductor integrated circuit comprising a plurality of flip-flops, the method comprising:

inputting data to a scan-chain while supplying a clock signal to the plurality of flip-flops so that the data is set in the plurality of flip-flops;

retaining the data in the plurality of flip-flops while inhibiting the clock signal for a predetermined period;

restarting the clock signal to the plurality of flip-flops so that the data retained in the plurality of flip-flops is output from the scan-chain; and

comparing the data output from the scan-chain and the data input to the scan-chain to test data retention of the plurality of flip-flops.

Another exemplary embodiment provides an exemplary method of testing a semiconductor integrated circuit, comprising a logic circuit and a plurality of flip-flops including a data retention flip-flop, the logic circuit being supplied with a high supply voltage and a low supply voltage during an active mode so that the logic circuit outputs a logic signal, at least one of the high supply voltage and the low supply voltage being discontinued to the logic circuit during a sleep mode, the data retention flip-flop being supplied with the high supply voltage, the low supply voltage, and a clock signal during the active mode so that the data retention flip-flop acquires the logic signal output from the logic circuit in synchronous with the clock signal, supply of the clock signal to the data retention flip-flop being discontinued, while supply of the high supply voltage and the low supply voltage is continued, during the sleep mode so that the data retention flip-flop retains the logic signal acquired during the active mode, the method comprising:

connecting the plurality of flip-flops in series so that the plurality of flip-flops forms a scan-chain;

inputting data to the scan-chain while supplying a clock signal to the plurality of flip-flops so that the data is set in the plurality of flip-flops;

retaining the data in the plurality of flip-flops while inhibiting the clock signal for a predetermined period;

restarting the clock signal to the plurality of flip-flops so that the data retained in the plurality of flip-flops is output from the scan-chain; and

comparing the data output from the scan-chain and the data input to the scan-chain to test data retention of the data retention flip-flop.

In certain exemplary embodiments, during the sleep mode, the data retention flip-flop is brought into a power-saving mode in which the data retention flip-flop is supplied with at least one of the high supply voltage and the low supply voltage at a reduced level compared with a level supplied in the active mode; and the data retention flip-flop that forms the scan-chain is brought into the power-saving mode during a predetermined period.

In the above-described methods, the data retention ability of a plurality of flip-flops, which composes a scan-chain, is tested together at the same time.

### BRIEF DESCRIPTION OF THE DRAWINGS

FIG. 1 shows a block diagram of a scan-chain composed of the flip-flop shown in FIG. 4.

FIG. 2 shows wave-shapes drawn from an exemplary test method according to this disclosure.

FIG. 3 shows a circuit of a related art flip-flop.

FIG. 4 shows an exemplary circuit of a tested flip-flop usable with the disclosed methods.

### DETAILED DESCRIPTION OF EMBODIMENTS

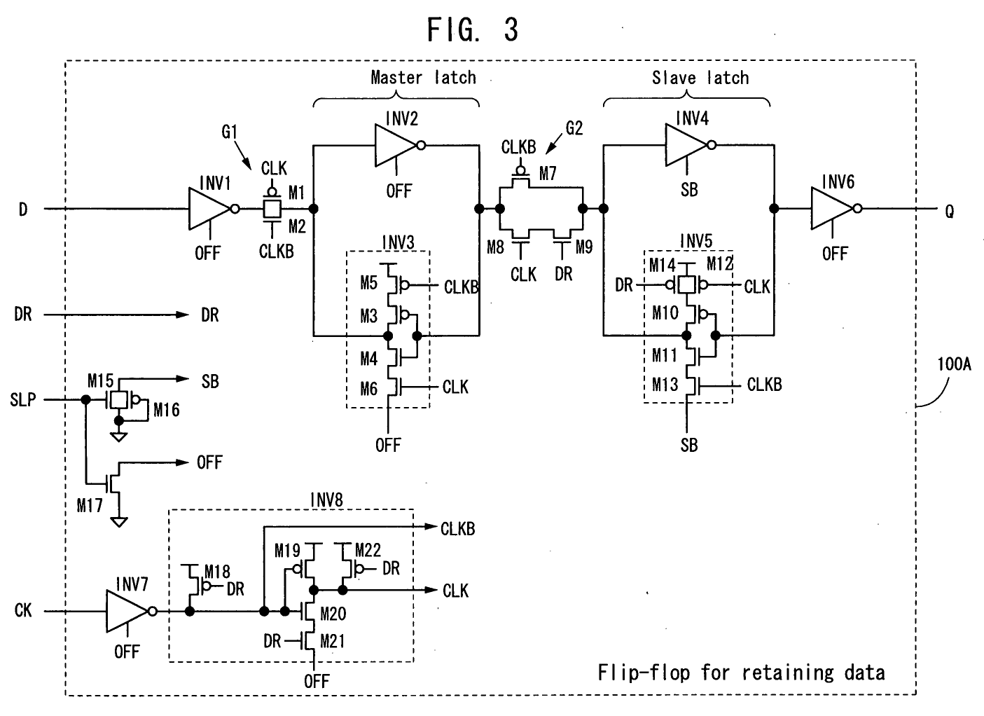

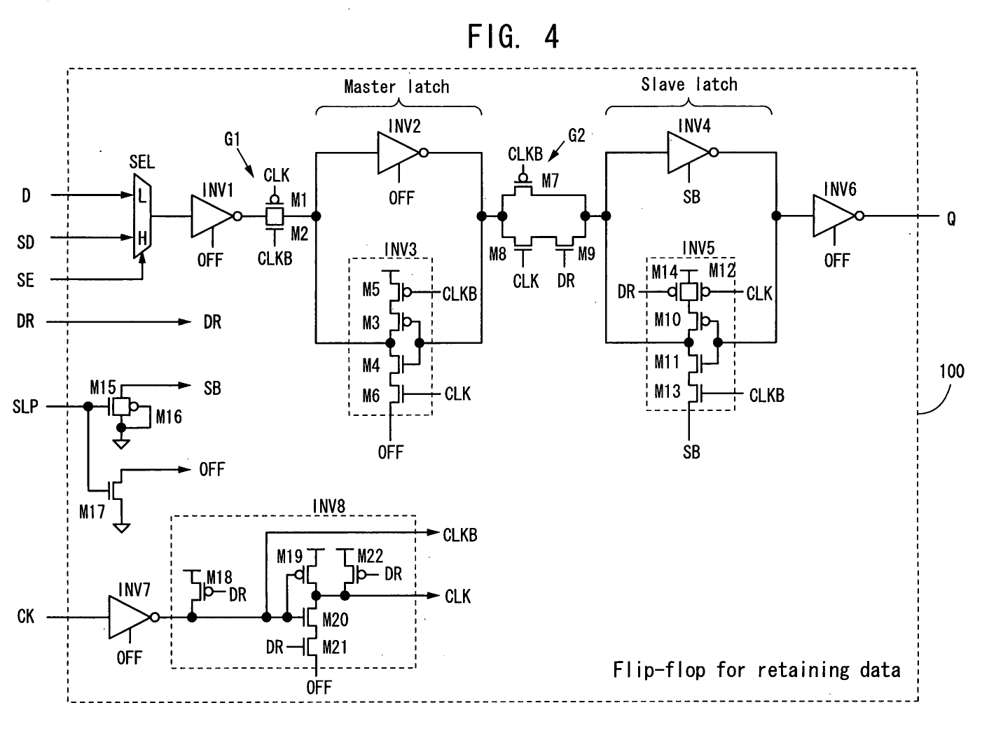

An exemplary embodiment of the disclosed method is explained below. FIG. 4 shows a construction of an exemplary data retention flip-flop to be tested using various exemplary test methods according to this disclosure. In FIG. 4, the same symbols are used for the same components used in FIG. 3. In the exemplary data retention flip-flop shown in FIG. 4, a selector SEL is connected to the input terminal of inverter INV1. The selector SEL has SD terminal to which the scan data SD is input, and D terminal to which the data D in a normal operation is input. One of the terminals SD and D is selected by selecting a logic of scan enable signal SE input to SE terminal of the selector. That is, when the terminal SE is set to “L”, the terminal D is selected. When the terminal SE is set to “H”, the terminal SD is selected.

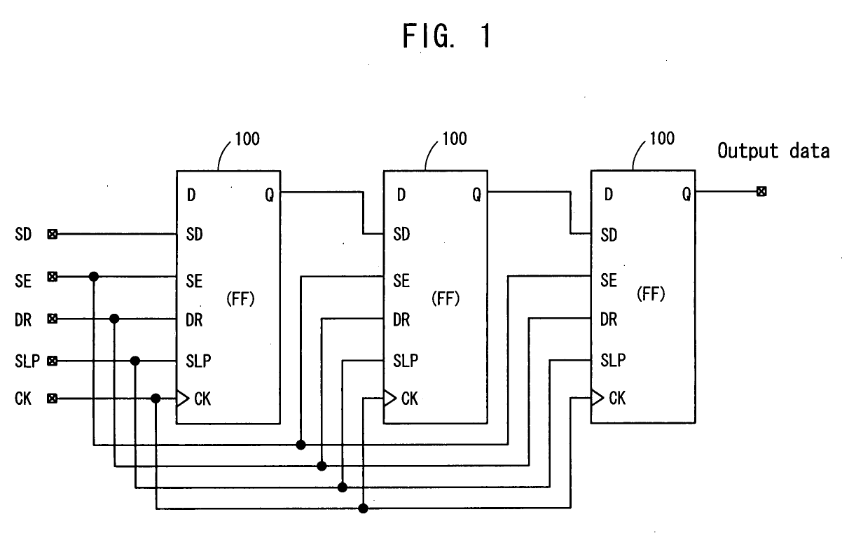

In a semiconductor integrated circuit, a plurality of data retention flip-flops, such as the exemplary data retention flip-flop shown in FIG. 4, and a plurality of logic circuits, are alternately connected to construct data transfer circuits (not shown). In the scan test, the plurality of data retention flip-flops is connected in series, while maintaining the connections with the logic circuits in the data transfer circuits. That is, as shown in FIG. 1, the terminal Q of the data retention flip-flop 100 in the preceding stage is connected to the terminal SD of the data retention flip-flop 100 in the next stage. Thus, a plurality of flip-flops 100 is connected in series form a scan-chain. FIG. 1 shows a part of a scan-chain including three stages of the flip-flops.

When inputting data into the scan-chain, the terminal SLP, in which the sleep signal SLP is input, and the terminal DR, in which the data retention signal DR is input, are both set to “H”. Further, the terminal SE is set to “H” and the terminal SD is selected. Thereby, the scan data SD is input to the terminal SD of the first flip-flop 100. As a result, the scan data SD input to the flip-flop 100 is forwarded through the plurality of flip-flops 100 in the scan-chain by supplying the clock signal CK.

Accordingly, it is possible to input and set desired data in each data retention flip-flop 100 in the scan-chain by continuing to supply the clock signal CK for a required period, or by supplying a number of required cycles of the clock signal CK, while inputting the scan data SD to the terminal SD of the data retention flip-flop 100 in the first stage.

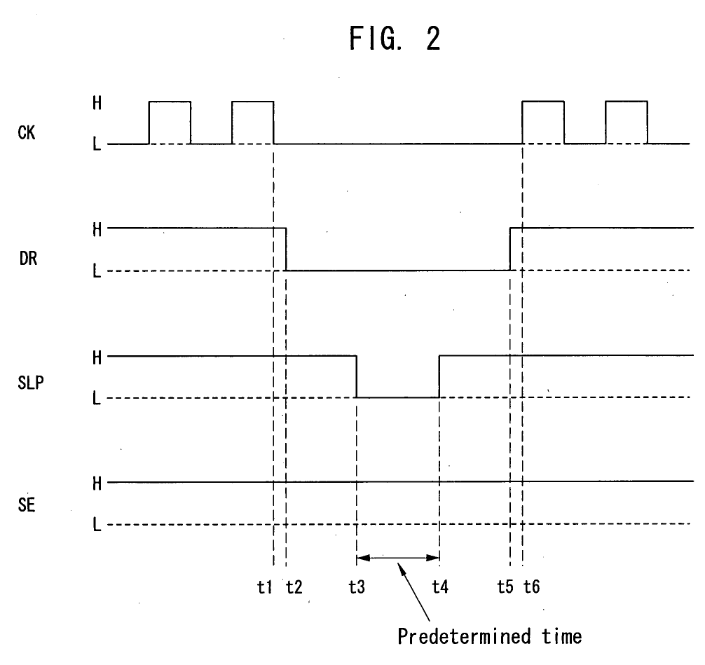

FIG. 2 shows a timing chart during an exemplary procedure of testing the scan-chain according to this disclosure. Firstly, setting the desired data in each of the flip-flops 100 is completed at the timing t1 by supplying the clock signal CK for a required period. At the timing t1, supply of the clock signal CK is discontinued and fixed to “L”. As a result, the transmission gate G2 is turned off and the master latch and the slave latch are separated. At the timing t2, the data retention signal DR is turned to “L”. At this moment, the transmission gate G2 is kept off, and the slave latch continues to retain the data. When the sleep signal SLP is turned to “L” at the timing t3, the transistor M17 turns off and the power supply routes from the GND to inverters INV1, INV2, INV3, INV6, INV7 and INV8 are shut off. At this time, however, the minimum required power supply to the inverters INV4 and INV5 is maintained by transistor M16. Thus, the slave latch continues to retain data.

As explained above, supply of the clock signal CK to the data retention flip-flops 100 is discontinued. The data retention flip-flops 100 are brought into the data retention mode and further into the power saving mode. This state of the flip-flops 100 is continued for a predetermined period. The predetermined period is set appropriately according to required data retention performance, or data retention time of the data retention flip-flop 100 specified in the specification of the semiconductor integrated circuit. A period of about 1 ms is an example of a duration for a typical predetermined period. In the power saving mode, the data retention flip-flop 100 may be supplied with at least one of the high supply voltage and the low supply voltage at a reduced level compared with a level supplied in and active mode.

At the timing t4, after the predetermined period elapses, the sleep signal SLP is set to “H”, thereby to restart the supply of the GND supply voltage to inverters INV1, INV2, INV3, INV6, INV7 and INV8. As a result, the data retained in the slave latch in each of the data retention flip-flops 100 that constitute the scan-chain is output to the terminal Q through the inverter INV6. The data is input to terminal SD of the data retention flip-flop 100 in the next stage. At the timing t5, the data retention signal DR is set to “H”. As a result, the transistors M9 and M21 are turned on, and the transistors M14, M18, and M22 are turned off. Further, at the timing t6, the clock signal CK is restarted. As a result, transmission of the data in the scan-chain is restarted.

The data retained in each of the data retention flip-flops 100, which composes the scan-chain, is serially output from the terminal Q of the data retention flip-flop 100 in the final stage by continuing to supply the clock signal CK for a required period.

If each of the data retention flip-flops 100 that constitute the scan-chain has a required data retention ability, each of the data retention flip-flops 100 retains the same data as set before the timing t1, even after the procedure shown in FIG. 2, which includes discontinuing supply of the clock signal CK, commencing the data retention mode by setting the data retention signal DR to “L”, and commencing the power saving mode by setting the sleep signal SLP to “L”. In this case, the data output from the terminal Q of the data retention flip-flop 100 in the final stage is the same as the data serially input from the terminal SD of the data retention flip-flop 100 in the first state.

Even if one or more of the data retention flip-flops 100 that constitute the scan-chain do not have the required data retention ability, the serially input signal may be accurately set in the flip-flops 100. However, the data set in the flip-flops 100 that do not have the required retention ability will be lost during the procedure shown in FIG. 2, i.e., during the period that the supply of the clock signal CK is discontinued, or during the period that the data retention flip-flops 100 are brought into the data retention mode or further into the power saving mode. Accordingly, the data output from the terminal Q of the data retention flip-flop 100 in the final stage is different from the data serially input from the terminal SD of the data retention flip-flop 100 in the first stage.

Therefore, it is possible to simultaneously test data retention abilities of a plurality of flip-flops 100 in a scan-chain by comparing the scan data SD input to the scan-chain and the data output from the scan-chain using a comparator (not shown in FIG. 1).

In the above exemplary embodiment, data retention abilities of a plurality of flip-flops 100 are tested by holding the scan-chain under the condition that the clock signal CK is fixed to “L”, the data retention signal DR is turned to “L” and the sleep signal SLP is turned to “L” for a predetermined period. The exemplary data retention flip-flop 100 shown in FIG. 4 can retain the data in the power saving mode by setting the data retention signal DR to “L” and then setting the sleep signal SLP to “L”. It is preferable to use the above exemplary test method for testing the data retention flip-flops 100 that can retain data during the power saving mode.

However, various other types of flip-flops that may be used as data retention flip-flops in a semiconductor integrated circuit may also be tested by the method according to this disclosure. For example, a flip-flop that cannot retain data during the power saving mode may be used as a data retention flip-flop for retaining data during a stand-by mode. In this case, supply of the power supply voltage to the logic circuit is discontinued during the stand-by mode. On the other hand, supply of the clock signal to the data retention flip-flop is discontinued while continuing to supply the power supply voltage to the flip-flop. Such a flip-flop may be tested by only discontinuing to supply the clock signal CK for a predetermined period.

Even in the case of testing the flip-flops which retain data during power saving mode, as shown in FIG. 4, it is not required to bring the flip-flops into the power saving mode during the predetermined period. It is also possible to test the retention ability of the flip-flop when the supply of the clock signal is discontinued by only fixing the clock signal CK to “L” for the predetermined period. In this case, the slave latch is separated from the master latch as described above, and the data is retained in the slave latch of the flip-flops.

Japanese Patent Laid-Open No. H11-112297 discloses still another type of data retention flip-flop. That is, FIG. 14 of Japanese Patent Laid-Open No. H11-112297 discloses a flip-flop that includes a latch and a memory. During the active mode, the data is stored in the latch. When the flip-flop moves into the stand-by mode, the data is transferred into the memory and retained in the memory during the stand-by mode. The data is read back into the latch when the flip-flop returns to the active mode.

The construction of this type of flip-flop is somewhat similar to that of the exemplary flip-flop 100 shown in FIG. 4 of the present application. That is, the latch and the memory in the flip-flop shown in FIG. 14 of Japanese Patent Laid-Open No. H11-112297 may correspond to the master latch and the slave latch, respectively, in the flip-flop 100 shown in FIG. 4 of the present application. In the flip-flop 100 shown in FIG. 4 of the present application, however, the data is stored in the master latch and then in the slave latch during the active mode. While, in the flip-flop shown in FIG. 14 of Japanese Patent Laid-Open No. H11-112297, the data is not entered into the memory (slave latch) during the active mode. When testing a flip-flop in which the data is not entered into the slave latch during the active mode and retains the data in the slave latch during the stand-by mode, the data serially input in the slave latch should be entered into the slave latch before the predetermined period.

It should be appreciated that various of the above-disclosed and other features and functions, or alternatives thereof, may be desirably combined. The above-described methods are intended to be illustrative and not limiting. Various presently unforeseen or unanticipated alternatives, modifications, variations or improvements may be subsequently made by those skilled in the art and are intended to be encompassed by the following claims.

What is claimed is:

1. A method of testing a semiconductor integrated circuit comprising a plurality of flip-flops, the method comprising:
connecting the plurality of flip-flops in series so that the plurality of flip-flops forms a scan-chain;
inputting data to the scan-chain while supplying a clock signal to the plurality of flip-flops so that the data is set in the plurality of flip-flops;
retaining the data in the plurality of flip-flops while inhibiting the clock signal for a predetermined period;
restarting the clock signal to the plurality of flip-flops so that the data retained in the plurality of flip-flops is output from the scan-chain; and
comparing the data output from the scan-chain and the data input to the scan-chain to test data retention of the plurality of flip-flops.

2. The method according to claim 1, wherein:
the semiconductor integrated circuit includes a logic circuit, the logic circuit being supplied with a high supply voltage and a low supply voltage during an active mode so that the logic circuit outputs a logic signal, at least one of the high supply voltage and the low supply voltage being discontinued to the logic circuit during a sleep mode; and
the plurality of flip-flops includes a data retention flip-flop, the data retention flip-flop being supplied with the high supply voltage, the low supply voltage, and the clock signal during the active mode so that the data retention flip-flop acquires the logic signal output from the logic circuit in synchronous with the clock signal, supply of the clock signal to the data retention flip-flop being discontinued, while the supply the high supply voltage and the low supply voltage is continued, during the sleep mode so that the data retention flip-flop retains the logic signal acquired during the active mode.

3. The method according to claim 2, wherein:
during the sleep mode, the data retention flip-flop is brought into a power-saving mode in which the data retention flip-flop is supplied with at least one of the high supply voltage and the low supply voltage at a reduced level compared with a level supplied in the active mode; and
the data retention flip-flop that forms the scan-chain is brought into the power-saving mode during the predetermined period.

4. The method according to claim 2, wherein the data retention flip-flop includes a selector that selects one of the signal output from the logic circuit and a signal from a preceding one of the plurality of flip-flops in the scan-chain.

5. The method according to claim 2, wherein the data retention flip-flop includes a master latch and a slave latch, supply of at least one of the high supply voltage and the low supply voltage to the master latch being discontinued, while supply to the slave latch of the high supply voltage and the low supply voltage is continued, during the predetermined period.

6. The method according to claim 5, further comprising entering the data, which is set in the master latch of the data retention flip-flop during the inputting data to the scan-chain, into the slave latch of the data retention flip-flop before the predetermined period.

7. A method of testing a semiconductor integrated circuit comprising a logic circuit and a plurality of flip-flops including a data retention flip-flop, the logic circuit being supplied with a high supply voltage and a low supply voltage during an active mode so that the logic circuit outputs a logic signal, at least one of the high supply voltage and the low supply voltage being discontinued to the logic circuit during a sleep mode, the data retention flip-flop being supplied with the high supply voltage, the low supply voltage, and a clock signal during the active mode so that the data retention flip-flop acquires the logic signal output from the logic circuit in synchronous with the clock signal, supply of the clock signal to the data retention flip-flop being discontinued, while supply of the high supply voltage and the low supply voltage is continued, during the sleep mode so that the data retention flip-flop retains the logic signal acquired during the active mode, the method comprising:
connecting the plurality of flip-flops in series so that the plurality of flip-flops forms a scan-chain;
inputting data to the scan-chain while supplying a clock signal to the plurality of flip-flops so that the data is set in the plurality of flip-flops;
retaining the data in the plurality of flip-flops while inhibiting the clock signal for a predetermined period;
restarting the clock signal to the plurality of flip-flops so that the data retained in the plurality of flip-flops is output from the scan-chain; and
comparing the data output from the scan-chain and the data input to the scan-chain to test data retention of the data retention flip-flop.

8. The method according to claim 7, wherein:
during the sleep mode, the data retention flip-flop is brought into a power-saving mode in which the data retention flip-flop is supplied with at least one of the high supply voltage and the low supply voltage with a reduced level compared with a level supplied in the active mode; and
the data retention flip-flop that forms the scan-chain is brought into the power-saving mode during the predetermined period.

9. The method according to claim 7, wherein the data retention flip-flop includes a selector that selects one of the signal output from the logic circuit and a signal from a preceding one of the plurality of flip-flops in the scan-chain.

10. The method according to claim 7, wherein the data retention flip-flop includes a master latch and a slave latch, supply of at least one of the high supply voltage to the master latch being discontinued, while supply to the slave latch of the high supply voltage and the low supply voltage is continued, during the predetermined period.

11. The method according to claim 10, further comprising entering the data, which is set in the master latch of the data retention flip-flop during the inputting data to the scan-chain, into the slave latch of the data retention flip-flop before the predetermined period.
